(19) United States
(12) Patent Application Publication
(10) Pub. No.: US 2012/0043906 A1
(43) Pub. Date: Feb. 23, 2012

(54) Mixed-Signal Network for Generating Distributed Electrical Pulses

(76) Inventor: Steven Daniel Jones, Lafayette, CA (US)

(21) Appl. No.: 13/215,147

(22) Filed: Aug. 22, 2011

Related U.S. Application Data
(60) Provisional application No. 61/376,239, filed on Aug. 23, 2010.

(51) Int. Cl. H05B 37/02; H03K 3/00

(52) U.S. Cl. 315/246; 327/298

(57) ABSTRACT

A mixed-signal network for generating distributed electrical pulses includes a control device and one or more networked mixed-signal devices. The control device generates digital and analog outputs that are directly connected to, or daisy-chained between, the networked mixed-signal devices. Each mixed-signal device responds under certain input conditions by generating one or more electrical pulses with characteristics controllable by the control device.

### CROSS REFERENCE TO RELATED APPLICATION

The present application claims the benefit, under 35 U.S.C.§119(e), of U.S. Provisional Application Ser. No. 61/376,239, filed Aug. 23, 2010, entitled “Mixed Signal Pulse Width Generators with Series Time-Division Control.”

### BACKGROUND

1. Field

The present application relates generally to the generation of electrical pulses with controllable characteristics. More particularly, this application relates to generating distributed electrical pulses by member devices of a mixed-signal network.

2. Related Art

Distributed pulse generating networks, particularly in the field of addressable lighting, are known technologies that continue to grow in popularity. Current technologies rely on intelligence at each pulse-generating node in the form of general purpose microcontrollers or application-specific integrated circuits. Those intelligent circuits interpret digital communication protocols and often also generate the electrical pulses with characteristics as described by the digital data they interpret.

U.S. Pat. No. 6,016,038 to Mueller (2000), U.S. Pat. No. 6,608,453 to Morgan (2003), and U.S. Pat. No. 6,548,967 to Dowling (2003) all describe nodes containing controllers for pulse generation, device address and data interpretation, or both. Similarly, off-the-shelf node controllers, such as the Worldsemi WS2801, Allegro A6281, Toshiba TCA62724FMG, National Semiconductor LM3549, NJR NJU6060V, and NXP's line of 12C controllers, all rely on expensive digital networks and are themselves relatively expensive when driving inexpensive circuitry.

When the generated electrical pulses are used to drive relatively inexpensive circuitry, like an LED, control circuitry represents a significant portion of each node's cost. Thus, the incremental cost of adding more nodes to such a network is often far more than the cost of the devices getting pulsed. Furthermore, by relying on digital communication protocols, pulse characteristics are discretized into an integral number representable by the digital protocol (16, 32, or 128 possible values, for example). Thus, many current technologies cannot slowly vary their pulse characteristics, like slowly fading an LED from fully-off to fully-on, for example, without noticeable and often distracting steps.

It would be highly desirable to reduce the cost per node while maintaining finely controllable pulse characteristics.

### SUMMARY

In one exemplary embodiment, a mixed-signal network for generating distributed electrical pulses includes a control device and a plurality of networked mixed-signal devices connected in series. The control device generates an analog TIME, digital SELECT, and digital CLOCK signals. Each mixed-signal device shares a common CLOCK and TIME bus, but daisy-chains SELECT from one mixed-signal device to the next. SELECT is buffered and delayed at each mixed-signal device by a time related to CLOCK in order to provide time-division access of TIME to each mixed-signal device in the network. When a mixed-signal device's SELECT is active, TIME is used to charge an internal energy storage device. When SELECT becomes inactive, the energy storage device discharges, where the discharge time is related to the generated PULSE output's pulse width. Thus, by controlling SELECT, CLOCK, and TIME, a control device can individually control the characteristics of PULSE pulses generated by each mixed-signal device in its network.

### BRIEF DESCRIPTION OF THE FIGURES

FIG. 1 depicts an abstract mixed-signal device circuit diagram.

FIG. 2 depicts an abstract chain of mixed-signal devices as the nodes in a pulse generating network.

FIG. 3 depicts a specific mixed-signal device embodiment designed to support the generation of LED pulses from 0% to 10% duty cycle at 10 kHz.

FIG. 4 depicts a specific mixed-signal network embodiment including a control device and a plurality of mixed-signal devices.

FIG. 5 depicts various generated pulse characteristics measured in the circuit depicted in FIG. 3 when the analog TIME signal is 0, 1, 1.5, 2.5, and 5 volts.

FIG. 6 depicts waveforms within a mixed-signal network as depicted in FIG. 4, with a control device and 300 mixed-signal devices.

### DETAILED DESCRIPTION

The structure and operation of a preferred embodiment will now be described. It should be understood that many other ways of practicing the inventions herein are available, and the embodiments described herein are exemplary and not limiting.

A mixed-signal network for generating distributed electrical pulses includes a control device and a plurality of networked mixed-signal devices connected in series.

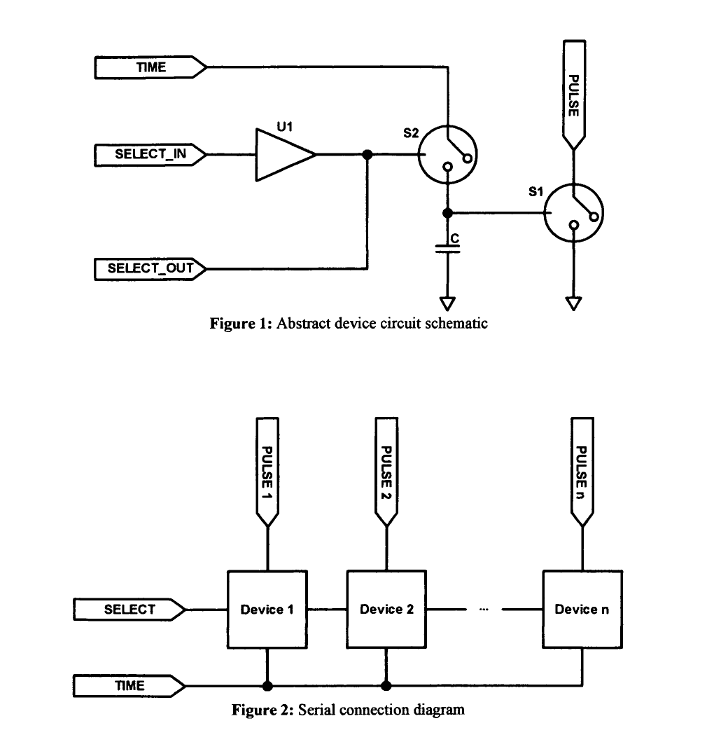

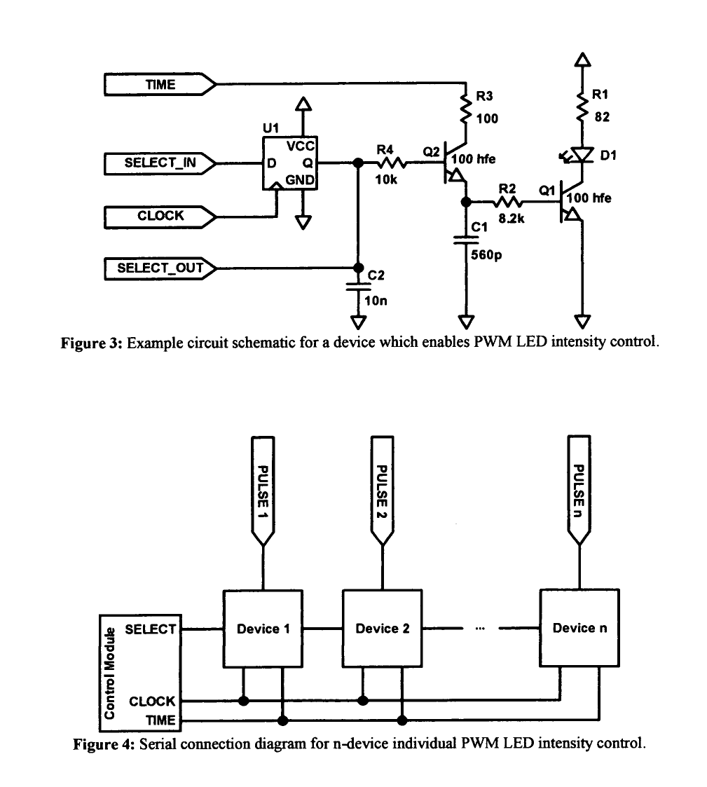

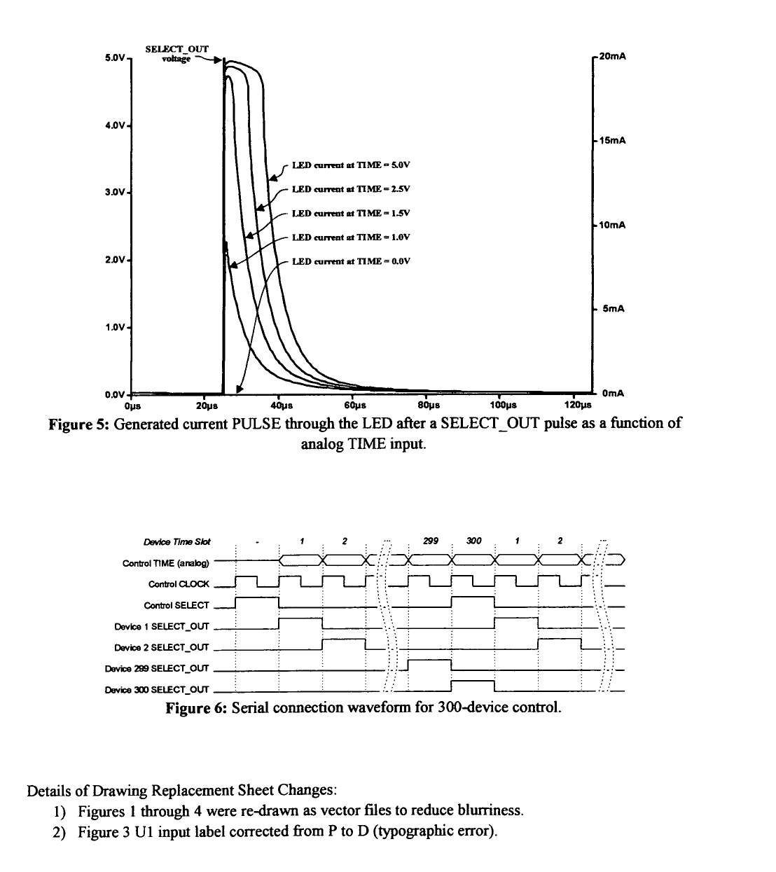

Mixed-signal devices have digital SELECT_IN and analog TIME inputs, and digital SELECT_OUT and analog PULSE outputs. Inputs are translated to outputs in the device as follows: the SELECT_IN signal feeds into the digital buffer (FIG. 1: U1), which generates a SELECT_OUT signal. SELECT_OUT enables a switch (FIG. 1: S2) which charges an energy storage device (FIG. 1: capacitor C1) to a level related to the analog TIME input. This stored energy enables a second switch (FIG. 1: S1) and generates a PULSE output for a time duration related to SELECT_OUT and the time it takes to discharge the energy storage device once SELECT_OUT toggles, disabling S2.

When multiple such circuits are connected in series as in FIG. 2, because only those stages whose SELECT_OUT is enabled have access to the analog TIME signal (i.e. to charge C through S2 in FIG. 1), the delayed nature of SELECT_OUT at each stage enables multiple devices to remain individually controllable while sharing a single TIME input by utilizing a time-division access technique.

In one embodiment, each stage is designed as an LED driver that enables pulse width modulation for intensity control (FIG. 3). Here, the digital buffer is a D-type flip-flop (U1) with an additional CLOCK input, the switches are BJT transistors (Q1 and Q2), and C2 is an optional capacitive load for U1's output to improve performance. Resistor and capacitor values are chosen carefully to generate a 10 kHz PWM approximation on the LED with duty cycles between zero and ten percent (see FIG. 5) when driven by a 3 MHz CLOCK, 3 MHz, 1/300 duty cycle PULSE_IN, zero to five volt TIME, and five volt power to ground.

These stages can be connected in series as in FIG. 4. With the design parameters mentioned, this arrangement supports individually controlling the intensity of up to 300 series-connected devices when one device accesses the TIME signal at a time (see FIG. 6). To support such a system, the control module must generate TIME with both adequate settling time (less than 10% of a CLOCK period, for example), and adequate drive strength (more than 50 mA, for example); failure to do so may create noticeable PULSE artifacts.

Differential signals and/or AC coupling can be employed if noise immunity, reduced EMI generation, or safety necessitates.

What is claimed is:

1. A mixed signal network for generating distributed electrical pulses, the mixed signal network comprising:
a. a control device providing at least one digital output and at least one analog output
b. at least one mixed-signal device connected to at least one of said control device's said digital outputs and at least one of said control device's analog outputs where said at least one mixed-signal device responds to its said at least one digital input by charging at least one energy storage device disposed within said at least one mixed-signal device to a level related to said at least one mixed-signal device analog inputs and discharging said at least one energy storage device when said at least one digital input changes state where each said at least one mixed-signal device generates an electrical pulse with characteristics related to the said at least one energy storage device energy.

2. A mixed-signal network for generating distributed electrical pulses as claimed in claim 1 where at least one said mixed-signal device includes a lighting element which responds to the said electrical pulse generated by said mixed-signal device.

3. A mixed-signal network for generating distributed electrical pulses as claimed in claim 1 where at least one said mixed-signal device includes at least one digital buffer which responds to at least one said digital input by generating a delayed version of another said at least one digital input as at least one digital output.
